(19) United States
(12) Patent Application Publication
(10) Pub. No.: US 2023/0216460 A1
(43) Pub. Date: Jul. 6, 2023

(54) Transmitter circuit

(71) Applicant: REALTEK SEMICONDUCTOR CORPORATION, Hsinchu (TW)

(72) Inventors: Chien-Hui TSAI, Hsinchu (TW); Hung-Chen CHU, Hsinchu (TW); Yung-Tai CHEN, Hsinchu (TW); Sheng-Yang HO, Hsinchu (TW)

(21) Appl. No.: 18/074,546

(22) Filed: Dec. 5, 2022

(30) Foreign Application Priority Data
Jan. 3, 2022 (TW) 111100139

(51) Int. Cl. H03F 3/45; H03F 1/56

(52) U.S. Cl. CPC H03F 3/45475; H03F 1/56; H03F 2200/387

(57) ABSTRACT

A transmitter circuit is provided. The transmitter circuit has an input port, a first transmission node, a second transmission node, a third transmission node, and a fourth transmission node and includes a first operational amplifier, a first output stage, a first resistor-capacitor network, a first switch group coupled between the first resistor-capacitor network and the input port, a first impedance matching circuit coupled to the first output stage, the first transmission node, and the second transmission node, a second operational amplifier, a second output stage, a second resistor-capacitor network, a second switch group coupled between the second resistor-capacitor network and the input port, and a second impedance matching circuit coupled to the second output stage, the third transmission node, and the fourth transmission node.

### BACKGROUND OF THE INVENTION

### 1. Field of the Invention

The present invention generally relates to the Ethernet, and, more particularly, to Ethernet transmitter circuits.

### 2. Description of Related Art

FIG. 1 shows a functional block diagram of a conventional Ethernet transmitter. The transmitter circuit 101 includes a first channel and a second channel.

The first channel includes an operational amplifier 104_t, an output stage 130_t, a resistor-capacitor circuit (RC circuit) 110_t, a resistor-capacitor circuit 120_t, an impedance matching circuit 140_t, and a switch-resistor network (SR network) 146_t. The resistor-capacitor circuit 110_t is coupled between the output terminal (the terminal that outputs the signal vop_t) of the output stage 130_t and the input terminal (the terminal that receives the signal vip_t) of the operational amplifier 104_t. The resistor-capacitor circuit 120_t is coupled between the output terminal (the terminal that outputs the signal von_t) of the output stage 130_t and the input terminal (the terminal that receives the signal vin_t) of the operational amplifier 104_t. The impedance matching circuit 140_t includes a switch-resistor network 142_t and a switch-resistor network 144_t. The switch-resistor network 142_t is coupled between the output terminal of the output stage 130_t and the transmission node txop, and the switch-resistor network 144_t is coupled between the output terminal of the output stage 130_t and the transmission node txon. The transmission node txop and the transmission node txon are coupled to the load resistor RL1 through the transformer 150_t.

The second channel includes an operational amplifier 104_r, an output stage 130_r, a resistor-capacitor circuit 110_r, a resistor-capacitor circuit 120_r, an impedance matching circuit 140_r, and a switch-resistor network 146_r. The resistor-capacitor circuit 110_r is coupled between the output terminal (the terminal that outputs the signal vop_r) of the output stage 130_r and the input terminal (the terminal that receives the signal vip_r) of the operational amplifier 104_r. The resistor-capacitor circuit 120_r is coupled between the output terminal (the terminal that outputs the signal von_r) of the output stage 130_r and the input terminal (the terminal that receives the signal vin_r) of the operational amplifier 104_r. The impedance matching circuit 140_r includes a switch-resistor network 142_r and a switch-resistor network 144_r. The switch-resistor network 142_r is coupled between the output terminal of the output stage 130_r and the transmission node rxip, and the switch-resistor network 144_r is coupled between the output terminal of the output stage 130_r and the transmission node rxin. The transmission node rxip and the transmission node rxin are coupled to the load resistor RL2 through the transformer 150_r.

Among the above-mentioned components, the transformer 150_t, the transformer 150_r, the load resistor RL1, and the load resistor RL2 are located outside a chip, while others are inside the chip.

When the transmitter circuit 101 operates in the medium dependent interface (MDI) mode, the operational amplifier 104_t, the output stage 130_t, the resistor-capacitor circuit 110_t, and the resistor-capacitor circuit 120_t are enabled, the operational amplifier 104_r, the output stage 130_r, the resistor-capacitor circuit 110_r, and the resistor-capacitor circuit 120_r are disabled, the switch-resistor network 142_t, the switch-resistor network 144_t, and the switch-resistor network 146_r are short-circuited, the switch-resistor network 142_r, the switch-resistor network 144_r, and the switch-resistor network 146_t are open, and the transmitter circuit 101 outputs the signals (the signal vip_t and signal vin_t) generated by the digital-to-analog converter (DAC) 102_t through the transmission node txop and the transmission node txon.

When the transmitter circuit 101 operates in a medium dependent interface crossover (MDIX) mode, the operational amplifier 104_t, the output stage 130_t, the resistor-capacitor circuit 110_t, and the resistor-capacitor circuit 120_t are disabled, the operational amplifier 104_r, the output stage 130_r, the resistor-capacitor circuit 110_r, and the resistor-capacitor circuit 120_r are enabled, the switch-resistor network 142_t, the switch-resistor network 144_t, and the switch-resistor network 146_r are open, the switch-resistor network 142_r, the switch-resistor network 144_r, and the switch-resistor network 146_t are short-circuited, and the transmitter circuit 101 outputs the signals (the signal vip_r and signal vin_r) generated by the DAC 102_r through the transmission node rxip and the transmission node rxin.

Due to the process variations, the switch-resistor network 142_t, the switch-resistor network 144_t, the switch-resistor network 142_r, and the switch-resistor network 144_r usually need to be calibrated. FIG. 2 is a schematic diagram of the switch-resistor network 142_t. Note that the circuits of the switch-resistor network 144_t, the switch-resistor network 142_r, and the switch-resistor network 144_r are similar to the switch-resistor network 142_t. A conventional calibration method is to provide multiple resistor (R0 to Rn)-switch (SW0 to SWn) pairs that are connected in parallel, so that different equivalent resistance values are generated by turning on or off the switches (SW0 to SWn). The switches SW0 to SWn in FIG. 2 are embodied by transmission gates, and the signals powb_h, pow_h, tap_h, and tapb_h are the control signals of the transmission gates.

In the transmitter circuit 101, the switch SWp_t can be used to control the switch-resistor network 142_t to form a short circuit (the switch SWp_t is turned on) or an open circuit (the switch SWp_t is turned off). However, the transmission gates fabricated by the advanced manufacturing process are low in withstanding voltage (i.e., cannot withstand high voltages), so the switch-resistor network 142_t, the switch-resistor network 144_t, the switch-resistor network 142_r, and the switch-resistor network 144_r in the conventional circuit should not be fabricated by the advanced manufacturing process; that is to say, when fabricated by the advanced manufacturing process, the switch-resistor network 142_t, the switch-resistor network 144_t, the switch-resistor network 142_r, and the switch-resistor network 144_r cannot actually be switched (turned on or off). Therefore, a transmitter circuit that can be switched (to achieve the purpose of a switch) under the advanced manufacturing process is needed.

### SUMMARY OF THE INVENTION

In view of the issues of the prior art, an object of the present invention is to provide transmitter circuits, so as to make an improvement to the prior art.

According to one aspect of the present invention, a transmitter circuit is provided. The transmitter circuit has an input port, a first transmission node, a second transmission node, a third transmission node, and a fourth transmission node. The transmitter circuit includes a first operational amplifier; a first output stage coupled to the first operational amplifier; a first resistor-capacitor network coupled to the first output stage and the first operational amplifier; a first switch group coupled between the first resistor-capacitor network and the input port; a first impedance matching circuit coupled to the first output stage, the first transmission node, and the second transmission node; a second operational amplifier; a second output stage coupled to the second operational amplifier; a second resistor-capacitor network coupled to the second output stage and the second operational amplifier; a second switch group coupled between the second resistor-capacitor network and the input port; and a second impedance matching circuit coupled to the second output stage, the third transmission node, and the fourth transmission node.

According to another aspect of the present invention, a transmitter circuit is provided. The transmitter circuit has a first transmission node, a second transmission node, a third transmission node, and a fourth transmission node. The transmitter circuit includes an operational amplifier; a first output stage coupled to the operational amplifier; a first resistor-capacitor network coupled to the first output stage; a first switch group coupled between the first resistor-capacitor network and the operational amplifier; a first impedance matching circuit coupled to the first output stage, the first transmission node, and the second transmission node; a second output stage coupled to the operational amplifier; a second resistor-capacitor network coupled to the second output stage; a second switch group coupled between the second resistor-capacitor network and the operational amplifier; a second impedance matching circuit coupled to the second output stage, the third transmission node, and the fourth transmission node; a common mode feedback (CMFB) circuit; a first switch coupled between the CMFB circuit and the first output stage; and a second switch coupled between the CMFB circuit and the second output stage.

In comparison with the prior art, the present invention solves the problems in the prior art because the transmitter circuit can be fabricated by the advanced manufacturing process.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 shows a functional block diagram of a conventional Ethernet transmitter.

FIG. 2 is a schematic diagram of a conventional switch-resistor network 142_t.

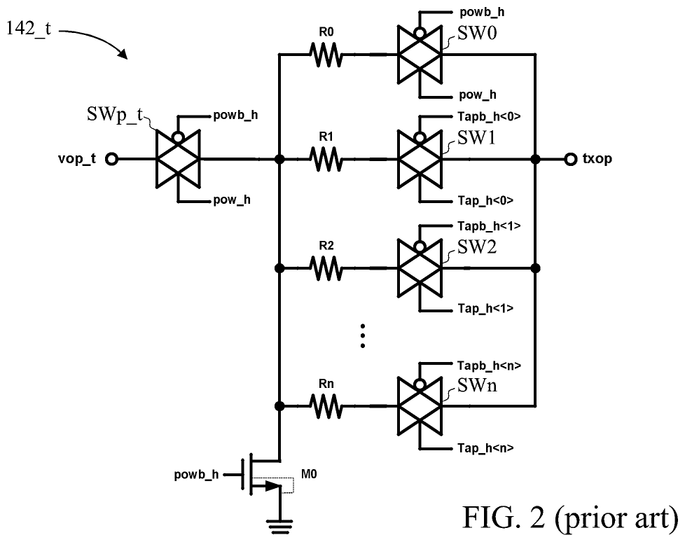

FIG. 3 shows a functional block diagram of an Ethernet transmitter according to an embodiment of the present invention.

FIG. 4 shows a functional block diagram of an Ethernet transmitter according to another embodiment of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes transmitter circuits. On account of that some or all elements of the transmitter circuits could be known, the detail of such elements is omitted provided that such detail has little to do with the features of this disclosure, and that this omission nowhere dissatisfies the specification and enablement requirements. A person having ordinary skill in the art can choose components equivalent to those described in this specification to carry out the present invention, which means that the scope of this invention is not limited to the embodiments in the specification.

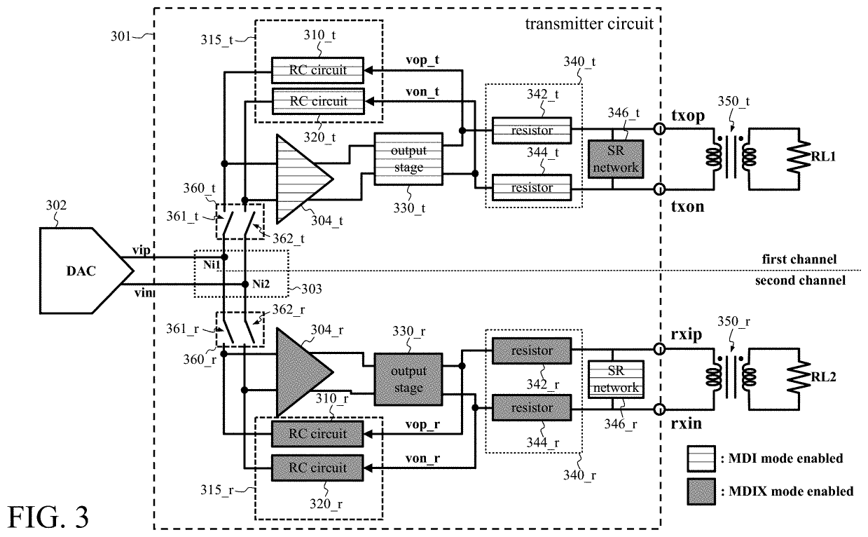

Reference is made to FIG. 3, which shows a functional block diagram of an Ethernet transmitter according to an embodiment of the present invention. The transmitter circuit 301 includes an input port 303 (including an input node Ni1 and an input node Ni2), a first channel, and a second channel.

The first channel receives input signals (e.g., the signal vip and the signal yin that the DAC 302 outputs) through the input port 303 and outputs signals through the transmission node txop and the transmission node txon.

The first channel includes an operational amplifier 304_t, a resistor-capacitor network 315_t (including a resistor-capacitor circuit 310_t and a resistor-capacitor circuit 320_t), an output stage 330_t, an impedance matching circuit 340_t (including a resistor 342_t and a resistor 344_t), a switch-resistor network 346_t, and a switch group 360_t (including a switch 361_t and a switch 362_t). The impedance matching circuit 340_t does not include any switch.

The operational amplifier 304_t is coupled or electrically connected to the output stage 330_t. The resistor-capacitor network 315_t is coupled between the output terminals of the output stage 330_t and the input terminals of the operational amplifier 304_t. One terminal of the resistor-capacitor circuit 310_t is coupled or electrically connected to one of the output terminals (the terminal that outputs the signal vop_t) of the output stage 330_t, and the other terminal of the resistor-capacitor circuit 310_t is coupled or electrically connected to one of the input terminals of the operational amplifier 304_t and the switch 361_t. One terminal of the resistor-capacitor circuit 320_t is coupled or electrically connected to the other output terminal (the terminal that outputs the signal von_t) of the output stage 330_t, and the other terminal of the resistor-capacitor circuit 320_t is coupled or electrically connected to the other input terminal of the operational amplifier 304_t and the switch 362_t.

One terminal of the resistor 342_t is coupled or electrically connected to one of the output terminals (the terminal that outputs the signal vop_t) of the output stage 330_t, and the other terminal of the resistor 342_t is coupled or electrically connected to the transmission node txop. One terminal of the resistor 344_t is coupled or electrically connected to the output terminal (the terminal that outputs the signal von_t) of the output stage 330_t, and the other terminal of the resistor 344_t is coupled or electrically connected to the transmission node txon. The switch-resistor network 346_t is coupled or electrically connected between the transmission node txop and the transmission node txon. The transmission node txop and the transmission node txon are coupled to the load resistor RL1 through the transformer 350_t.

The switch group 360_t is coupled between the input port 303 and the input terminals of the operational amplifier 304_t. The switch 361_t is coupled or electrically connected between the input node Ni1 and one of the input terminals (the input terminal coupled or electrically connected to the resistor-capacitor circuit 310_0 of the operational amplifier 304_t. The switch 362_t is coupled or electrically connected between the input node Ni2 and the other input terminal (the input terminal coupled or electrically connected to the resistor-capacitor circuit 320_t) of the operational amplifier 304_t.

The second channel receives input signals (e.g., the signal vip and the signal yin) through the input port 303 and outputs signals through the transmission node rxip and the transmission node rxin.

The second channel includes an operational amplifier 304_r, a resistor-capacitor network 315_r (including a resistor-capacitor circuit 310_r and a resistor-capacitor circuit 320_r), an output stage 330_r, an impedance matching circuit 340_r (including a resistor 342_r and a resistor 344_r), a switch-resistor network 346_r, and a switch group 360_r (including a switch 361_r and a switch 362_r). The impedance matching circuit 340_r does not include any switch.

The operational amplifier 304_r is coupled or electrically connected to the output stage 330_r. The resistor-capacitor network 315_r is coupled between the output terminals of the output stage 330_r and the input terminals of the operational amplifier 304_r. One terminal of the resistor-capacitor circuit 310_r is coupled or electrically connected to one of the output terminals (the terminal that outputs the signal vop_r) of the output stage 330_r, and the other terminal of the resistor-capacitor circuit 310_r is coupled or electrically connected to one of the input terminals of the operational amplifier 304_r and the switch 361_r. One terminal of the resistor-capacitor circuit 320_r is coupled or electrically connected to the other output terminal (the terminal that outputs the signal von_r) of the output stage 330_r, and the other terminal of the resistor-capacitor circuit 320_r is coupled or electrically connected to the other input terminal of the operational amplifier 304_r and the switch 362_r.

One terminal of the resistor 342_r is coupled or electrically connected to one of the output terminals (the terminal that outputs the signal vop_r) of the output stage 330_r, and the other terminal of the resistor 342_r is coupled or electrically connected to the transmission node rxip. One terminal of the resistor 344_r is coupled or electrically connected to the output terminal (the terminal that outputs the signal von_r) of the output stage 330_r, and the other terminal of the resistor 344_r is coupled or electrically connected to the transmission node rxin. The switch-resistor network 346_r is coupled or electrically connected between the transmission node rxip and the transmission node rxin. The transmission node rxip and the transmission node rxin are coupled to the load resistor RL2 through the transformer 350_r.

The switch group 360_r is coupled between the input port 303 and the input terminals of the operational amplifier 304_r. The switch 361_r is coupled or electrically connected between the input node Ni1 and one of the input terminals (the input terminal coupled or electrically connected to the resistor-capacitor circuit 310_r) of the operational amplifier 304_r. The switch 362_r is coupled or electrically connected between the input node Ni2 and the other input terminal (the input terminal coupled or electrically connected to the resistor-capacitor circuit 320_r) of the operational amplifier 304_r.

When the transmitter circuit 301 operates in the MDI mode, the operational amplifier 304_t, the output stage 330_t, the resistor-capacitor circuit 310_t, the resistor-capacitor circuit 320_t, the resistor 342_t, the resistor 344_t, and the switch-resistor network 346_r are enabled, the operational amplifier 304_r, the output stage 330_r, the resistor-capacitor circuit 310_r, the resistor-capacitor circuit 320_r, the resistor 342_r, the resistor 344_r, and the switch-resistor network 346_t are disabled, the switch group 360_t is turned on (i.e., the switch 361_t and the switch 362_t are turned on), and the switch group 360_r is turned off (i.e., the switch 361_r and the switch 362_r are turned off). In the MDI mode, the transmitter circuit 301 transmits through the transmission node txop and the transmission node txon the signal vip and the signal yin that the DAC 302 outputs.

When the transmitter circuit 301 operates in the MDIX mode, the operational amplifier 304_t, the output stage 330_t, the resistor-capacitor circuit 310_t, the resistor-capacitor circuit 320_t, the resistor 342_t, the resistor 344_t, and the switch-resistor network 346_r are disabled, the operational amplifier 304_r, the output stage 330_r, the resistor-capacitor circuit 310_r, the resistor-capacitor circuit 320_r, the resistor 342_r, the resistor 344_r, and the switch-resistor network 346_t are enabled, the switch group 360_t is turned off (i.e., the switch 361_t and the switch 362_t are turned off), and the switch group 360_r is turned on (i.e., the switch 361_r and the switch 362_r are turned on). In the MDIX mode, the transmitter circuit 301 transmits through the transmission node rxip and the transmission node rxin the signal vip and the signal yin that the DAC 302 outputs.

The operational amplifier 304_t and the operational amplifier 304_r each include a common mode feedback (CMFB) circuit. The details and operating principles of the CMFB circuit are well known to people having ordinary skill in the art and thus omitted for brevity.

Among the components in FIG. 3, the transformer 350_t, the transformer 350_r, the load resistor RL1, and the load resistor RL2 are located outside a chip, while others are inside the chip.

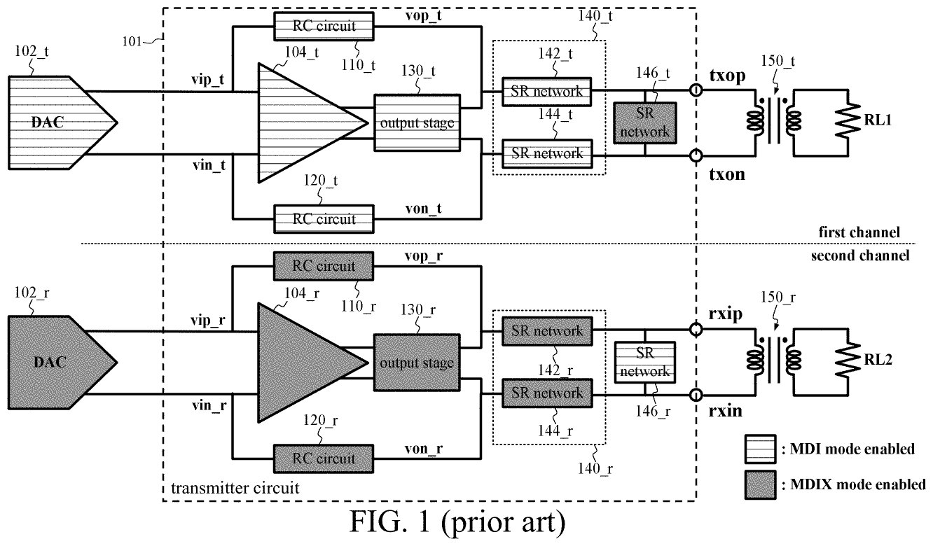

By turning on or off the switch 361_t, the switch 362_t, the switch 361_r, and the switch 362_r, the transmitter circuit 301 operates in the MDI mode or the MDIX mode. The switch 361_t, the switch 362_t, the switch 361_r, and the switch 362_r may be embodied by transistors. Since there are no large signal swings (i.e., no high voltages) on the switch 361_t, the switch 362_t, the switch 361_r, and the switch 362_r, the transmitter circuit 301 can be fabricated by the advanced manufacturing process. Of course, the transmitter circuit 301 can also be fabricated by the conventional manufacturing processes. In addition, compared with the transmitter circuit 101 of FIG. 1, the first channel and the second channel of the transmitter circuit 301 of the present invention share the DAC 302, which can reduce the circuit area and save costs.

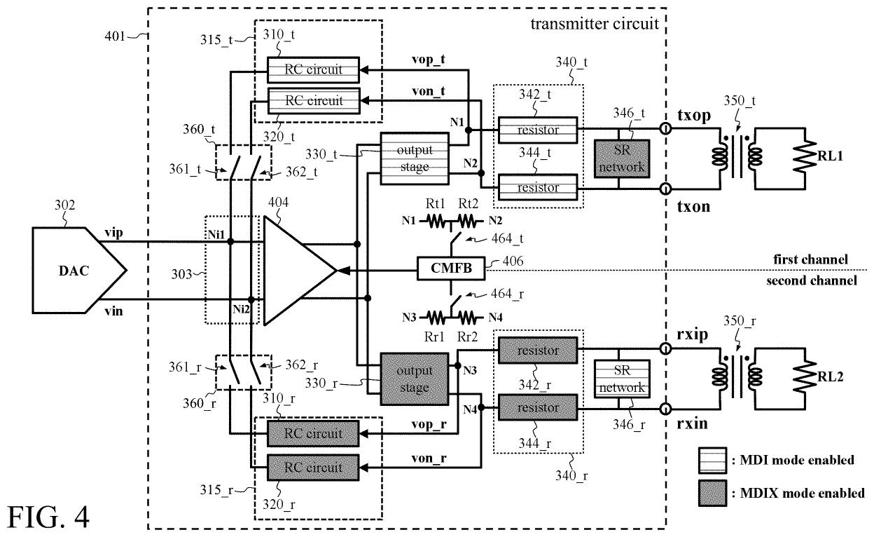

Reference is made to FIG. 4, which shows a functional block diagram of the Ethernet transmitter according to another embodiment of the present invention. The transmitter circuit 401 in FIG. 4 is similar to the transmitter circuit 301, except that the first channel and the second channel of the transmitter circuit 401 share the operational amplifier 404. The outputs of the operational amplifier 404 are coupled or electrically connected to both the output stage 330_t and the output stage 330_r. One of the input terminals of the operational amplifier 404 (the input terminal that receives the signal vip, i.e., the input node Ni1) is coupled to the resistor-capacitor circuit 310_t through the switch 361_t as well as coupled to the resistor-capacitor circuit 310_r through the switch 361_r; the other input terminal of the operational amplifier 404 (the input terminal that receives the signal yin, i.e., the input node Ni2) is coupled to the resistor-capacitor circuit 320_t through the switch 362_t as well as coupled to the resistor-capacitor circuit 320_r through the switch 362_r.

Since the operational amplifier 404 is shared, the CMFB circuit 406 of the operational amplifier 404 must switch between the first channel and the second channel. As shown in FIG. 4, the CMFB circuit 406 is coupled or electrically connected to the switch 464_t and the switch 464_r. The switch 464_t is coupled to the node N1 (i.e., one of the output terminals of the output stage 330_t) through the resistor Rt1 as well as coupled to the node N2 (i.e., the other output terminal of the output stage 330_t) through the resistor Rt2. The switch 464_r is coupled to the node N3 (i.e., one of the output terminals of the output stage 330_r) through the resistor Rr1 as well as coupled to the node N4 (i.e., the other output terminal of the output stage 330_r) through the resistor Rr2. The details and operating principles of the CMFB circuit 406 are well known to people having ordinary skill in the art and thus omitted for brevity.

When the transmitter circuit 401 operates in the MDI mode, the operational amplifier 404 is enabled, the switch 361_t, the switch 362_t, and the switch 464_t are turned on, and the switch 361_r, the switch 362_r, and the switch 464_r are turned off; when the transmitter circuit 401 operates in the MDIX mode, the operational amplifier 404 is enabled, the switch 361_t, the switch 362_t, and the switch 464_t are turned off, and the switch 361_r, the switch 362_r, and the switch 464_r are turned on.

The transmitter circuit 401 can also be fabricated by the advanced manufacturing process or the conventional manufacturing processes. In addition, compared with the transmitter circuit 301, since the operational amplifier 404 is further shared in the transmitter circuit 401, the circuit area and cost are further reduced.

Please note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A transmitter circuit having an input port, a first transmission node, a second transmission node, a third transmission node, and a fourth transmission node and comprising:
a first operational amplifier;
a first output stage coupled to the first operational amplifier;
a first resistor-capacitor network coupled to the first output stage and the first operational amplifier;
a first switch group coupled between the first resistor-capacitor network and the input port;
a first impedance matching circuit coupled to the first output stage, the first transmission node, and the second transmission node;
a second operational amplifier;
a second output stage coupled to the second operational amplifier;
a second resistor-capacitor network coupled to the second output stage and the second operational amplifier;
a second switch group coupled between the second resistor-capacitor network and the input port; and
a second impedance matching circuit coupled to the second output stage, the third transmission node, and the fourth transmission node.

2. The transmitter circuit of claim 1, wherein the first resistor-capacitor network comprises a first resistor-capacitor circuit and a second resistor-capacitor circuit, and the second resistor-capacitor network comprises a third resistor-capacitor circuit and a fourth resistor-capacitor circuit.

3. The transmitter circuit of claim 2, wherein the first switch group comprises a first switch and a second switch, and the second switch group comprises a third switch and a fourth switch.

4. The transmitter circuit of claim 3, wherein the input port comprises a first input node and a second input node, and the first switch is coupled between the first input node and the first resistor-capacitor circuit, the second switch is coupled between the second input node and the second resistor-capacitor circuit, the third switch is coupled between the first input node and the third resistor-capacitor circuit, and the fourth switch is coupled between the second input node and the fourth resistor-capacitor circuit.

5. The transmitter circuit of claim 1, wherein the first impedance matching circuit comprises a first resistor and a second resistor, and the second impedance matching circuit comprises a third resistor and a fourth resistor.

6. The transmitter circuit of claim 5, wherein the first resistor is coupled between the first output stage and the first transmission node, the second resistor is coupled between the first output stage and the second transmission node, the third resistor is coupled between the second output stage and the third transmission node, and the fourth resistor is coupled between the second output stage and the fourth transmission node.

7. The transmitter circuit of claim 1, wherein the transmitter circuit operates in a first mode or a second mode; in the first mode, the first switch group is turned on and the second switch group is turned off; in the second mode, the first switch group is turned off and the second switch group is turned on.

8. The transmitter circuit of claim 1, wherein the first impedance matching circuit and the second impedance matching circuit do not comprise any switch.

9. A transmitter circuit having a first transmission node, a second transmission node, a third transmission node, and a fourth transmission node and comprising:
an operational amplifier;
a first output stage coupled to the operational amplifier;
a first resistor-capacitor network coupled to the first output stage;
a first switch group coupled between the first resistor-capacitor network and the operational amplifier;
a first impedance matching circuit coupled to the first output stage, the first transmission node, and the second transmission node;
a second output stage coupled to the operational amplifier;
a second resistor-capacitor network coupled to the second output stage;
a second switch group coupled between the second resistor-capacitor network and the operational amplifier;
a second impedance matching circuit coupled to the second output stage, the third transmission node, and the fourth transmission node;
a common mode feedback (CMFB) circuit;
a first switch coupled between the CMFB circuit and the first output stage; and
a second switch coupled between the CMFB circuit and the second output stage.

10. The transmitter circuit of claim 9, wherein the first resistor-capacitor network comprises a first resistor-capacitor circuit and a second resistor-capacitor circuit, and the second resistor-capacitor network comprises a third resistor-capacitor circuit and a fourth resistor-capacitor circuit.

11. The transmitter circuit of claim 10, wherein the first switch group comprises a third switch and a fourth switch, and the second switch group comprises a fifth switch and a sixth switch.

12. The transmitter circuit of claim 11, wherein the operational amplifier has a first input terminal and a second input terminal, and the third switch is coupled between the first input terminal of the operational amplifier and the first resistor-capacitor circuit, the fourth switch is coupled between the second input terminal of the operational amplifier and the second resistor-capacitor circuit, the fifth switch is coupled between the first input terminal of the operational amplifier and the third resistor-capacitor circuit, and the sixth switch is coupled between the second input terminal of the operational amplifier and the fourth resistor-capacitor circuit.

13. The transmitter circuit of claim 9, wherein the first impedance matching circuit comprises a first resistor and a second resistor, and the second impedance matching circuit comprises a third resistor and a fourth resistor.

14. The transmitter circuit of claim 13, wherein the first resistor is coupled between the first output stage and the first transmission node, the second resistor is coupled between the first output stage and the second transmission node, the third resistor is coupled between the second output stage and the third transmission node, and the fourth resistor is coupled between the second output stage and the fourth transmission node.

15. The transmitter circuit of claim 9, wherein the transmitter circuit operates in a first mode or a second mode; in the first mode, the first switch group and the first switch are turned on, and the second switch group and the second switch are turned off; in the second mode, the first switch group and the first switch are turned off, and the second switch group and the second switch are turned on.

16. The transmitter circuit of claim 9, wherein the first impedance matching circuit and the second impedance matching circuit do not comprise any switch.
